(19) United States
(12) Patent Application Publication
(10) Pub. No.: US 2025/0060406 A1
(43) Pub. Date: Feb. 20, 2025

(54) Measurement Device for Process Metrology

(71) Applicant: Berthold Technologies GmbH & Co. KG, Bad Wildbad (DE)

(72) Inventors: Steffen MUELLER, Pforzheim (DE); Joerg BAEUERLE, Baiersbronn (DE); Tobias DAIBENZEIHER, Birkenfeld (DE)

(21) Appl. No.: 18/804,568

(22) Filed: Aug. 14, 2024

(30) Foreign Application Priority Data
Aug. 15, 2023 (DE) 10 2023 121 761.5

(51) Int. Cl. G01R 31/28

(52) U.S. Cl. CPC G01R 31/2839; G01R 31/2829

(57) ABSTRACT

A measurement device for process metrology, includes: a number n of sensors, wherein a respective sensor of the number n of sensors is designed to generate associated sensor data such that a total number n of sensor data is generated by way of the number n of sensors; a learning unit, wherein the learning unit is designed to calculate values of a number d of parameters of a hypothesis function based on training data; and a measurement device diagnostic unit, which is designed to calculate a number m of diagnostic values in dependence on the number n of sensor data based on the hypothesis function and the calculated values of the number d of parameters of the hypothesis function.

### CROSS REFERENCE TO RELATED APPLICATION

This application claims priority under 35 U.S.C. § 119 from German Patent Application No. 10 2023 121761.5, filed Aug. 15, 2023, the entire disclosure of which is herein expressly incorporated by reference.

### BACKGROUND AND SUMMARY

The invention is based on the object of providing a measurement device for process metrology, which can itself carry out diagnosis of its condition that is as simple and reliable as possible.

The measurement device has a number n of sensors, with n being a natural number greater than zero. For example, the number n can lie in a range between 1 and 12.

A respective sensor of the number n of sensors is designed to generate its associated sensor data, so that a total number n of sensor data is generated by means of the number n of sensors. For example, the sensor data are each data in digital representation, for example with a resolution of between 8 bit and 64 bit. For example, the digital sensor data are generated continuously at a predetermined temporal repetition rate. For example, every 100 ms, the data of all n sensors are generated simultaneously or with a known temporal relationship to one another.

The measurement device further comprises at least one measurement device diagnostic unit, which is designed to calculate a number m of diagnostic values in dependence on the number n of sensor data based on values of a number d of parameters. In particular, the number d of parameters are parameters of a hypothesis function h, which approximates a diagnostic function f. The sensor data can also be time-shifted. The number m is a natural number greater than zero and can lie in the range between 1 and 4, for example. The number d is a natural number greater than zero and can lie in the range between 1 and 500, for example.

The measurement device further comprises a learning unit, wherein the learning unit is designed to calculate the values of the number d of parameters based on training data.

The learning unit, the number of sensors, and the measurement device diagnostic unit can be provided spatially together or spatially separated from one another. For example, the number of sensors and the measurement device diagnostic unit may be arranged at the site of a measurement task, i.e. in the field, and the learning unit may be arranged spatially separated from it. The learning unit can be implemented, for example, by means of a powerful computer, which calculates the number d of parameters based on the training data, wherein the number d of parameters are then provided to the measurement device diagnostic unit, for example by transmitting the number d of parameters from the learning unit to the measurement device diagnostic unit via a data network. Of course, the learning unit and the measurement device diagnostic unit, and if appropriate the number n of sensors, can be integrated into a common physical device.

In one embodiment, the number m of diagnostic values relate to the remaining useful life and/or a status of components of the measurement device. For example, a diagnostic value of the number m of diagnostic values can map the remaining useful life and/or the status of an associated component of m components of the measurement device.

In one embodiment, the measurement device comprises a photomultiplier and a power supply for the photomultiplier, wherein the number m of diagnostic values relate to a remaining useful life and/or a status of the photomultiplier and the power supply.

In one embodiment, the number n of sensors is selected from the quantity of sensors consisting of: at least one sensor which is designed to detect a signal form of an analog pulse generated by the photomultiplier, at least one sensor which is designed to detect a temporal distribution between two analog pulses generated by the photomultiplier, at least one sensor which is designed to detect a radiometric spectrum, and at least one sensor which is designed to detect a temporal change in a radiometric spectrum.

Equipment failures in radiometric process metrology are costly and often dangerous because the measurement systems involved are the only source of information for process control. If a measurement device fails unexpectedly, it usually leads to a production stop, in the worst case even to an accident with a danger for humans.

Predicting equipment failure is difficult because the measurement systems used are extremely complex. The naive supervision of individual operating parameters is often not sufficient to detect equipment faults at an early stage. This would only be possible if a large number of operating parameters and higher-level expert knowledge were taken into account at the same time. Conventional measurement devices in radiometric process metrology do not yet do this.

With the present invention, the problem described above is solved in that the measurement device establishes the relationships between sensor or operating data and the remaining useful life and/or status of individual device components using methods of artificial intelligence, such as machine learning or deep learning, in an automated manner based on self-learning and without explicit knowledge of a mathematical formula, based on training data.

In one embodiment, the measurement device uses methods of supervised learning to determine the relationship between operating data and remaining useful life (RUL) of device components. Techniques of supervised learning, which are applied according to the invention for this purpose, are in particular artificial neural networks or support vector machines or decision trees/random forests.

The training data consist of a history of sensor data, which preceded a fault condition or a component failure. The measurement device thus independently learns the characteristic data signatures that can lead to a fault and can thus predict a remaining useful life.

In another embodiment, the measurement device uses methods of unsupervised learning to detect anomalies in sensor data and map them to a discrete status value of the respective device components.

Techniques of unsupervised learning, which are applied according to the invention for this purpose, may in particular be one of the following: Gaussian fitting, one-class support vector machine, principal component analysis, isolation forest, local outlier factor, autoencoder.

Training data consist of sensor data in the normal state of the system. The device thus independently learns the data signatures that characterize the normal state and can thus identify an abnormal state as such.

According to the invention, the training data can consist of both real field data and simulation data. The training process can take place once or several times, and offline or online.

The sensor data for the determination according to the invention of the remaining useful life and/or the status of device components can be selected, for example, from the set of the following sensor data:
signal form of the analog pulse (amplitude over time, sampled) generated by a photomultiplier (PM);
temporal distribution between two PM analog pulses or radiation particle events (histogram/statistical distribution);
static evaluation of a radiometric spectrum (number of events over energy or analog pulse amplitude), in particular the position and shape of the used radiation and/or the cosmic radiation and/or the noise edge;
temporal change in the radiometric spectrum at a constant count rate;
ratio between a measurement channel and an additional suitable control channel based on cosmic radiation control;
a bias voltage of a photomultiplier tube (PMT) or of a silicon photomultiplier (SiPM) (absolute value over temperature);
current through PMT or SiPM ((leakage) current over count rate and temperature);
general supply voltage and current consumption (voltage/current over count rate and temperature) of all function blocks of the measurement device;
generated control voltages of the measurement device (e.g. threshold values, setpoints);
slope and offset of calibration curves of ADC/DAC/PWM components in the measurement device;
mono-flop hold time of radiometric dead time compensation for counting rate determination;
frequency of the quartz used for the count rate calculation;
temporal derivation of a count rate signal;
operating hours of the measurement device (absolute number of hours and over temperature);
impedances of the transmission link at the output of the measurement device over time;
total energy consumption of the measurement device;
supply voltage of the measurement device;
acceleration sensor signal of the measurement device;
ratios of different temperature signals of the measurement device with respect to one another;
communication error/CRC over time within the measurement device;
communication error/CRC over time between the measurement device and an evaluation unit and/or a customer system;
statistical distribution of watchdog reboots of the measurement device;
the date of a radiation source stored in the measurement device;
temporal derivation of the process value determined by radiometry.

The measurement device relates these sensor data or input variables according to the invention to one another by means of artificial intelligence, instead of merely testing them in isolation against threshold values, as is customary in conventional solutions. The measurement device automatically and independently recognizes patterns in the data and can thus draw generalized conclusions about the current device status (keyword “learning transfer”).

This has, among others, the following advantages over the prior art.

The quality and accuracy of the calculated status messages is increased because the system learns all the process influences and error causes by means of the training data. In this way, relationships between individual variables or sensor data which would be difficult for a person to see are also learned. This results in a significant improvement in the probability of fault detection and failure prediction.

According to the invention, no explicit system of rules and no explicit threshold values for the operating data need to be known in radiometric process metrology. Rather, the system itself extracts the system of rules from the training data using artificial intelligence. The maintenance cycle and state of the device can thus be treated as a black box, the internal logic of which is unknown and is learned and organized by the device itself. This means that failures in new, previously unknown error scenarios for which no expert knowledge exists yet can be detected and predicted by means of the invention.

According to the invention, it is possible to provide information about pending problems related to individual device components early and reliably, even before they occur. This allows a user to plan maintenance work early and in a targeted manner, and to avoid any false alarms. Overall, operational safety is increased and maintenance costs are minimized.

The invention provides concrete statements about individual device components by way of detailed, reliable status messages. For example, a service technician can replace the affected components in a more targeted manner than before without having to make assumptions about any possible error causes. This saves costs.

Other objects, advantages and novel features of the present invention will become apparent from the following detailed description of one or more preferred embodiments when considered in conjunction with the accompanying drawings.

### BRIEF DESCRIPTION OF THE DRAWINGS

FIG. 1 shows highly schematically a block diagram of a measurement device according to an embodiment of the invention for process metrology;

FIG. 2 shows highly schematically a block diagram of an inner structure of an embodiment of a measurement device diagnostic unit of the measurement device for process metrology shown in FIG. 1;

FIG. 3 shows highly schematically a block diagram of an inner structure of a further embodiment of a measurement device diagnostic unit of the measurement device for process metrology shown in FIG. 1; and

FIG. 4 shows highly schematically a block diagram of the measurement device for process metrology shown in FIG. 1 in a learning mode.

### DETAILED DESCRIPTION OF THE DRAWINGS

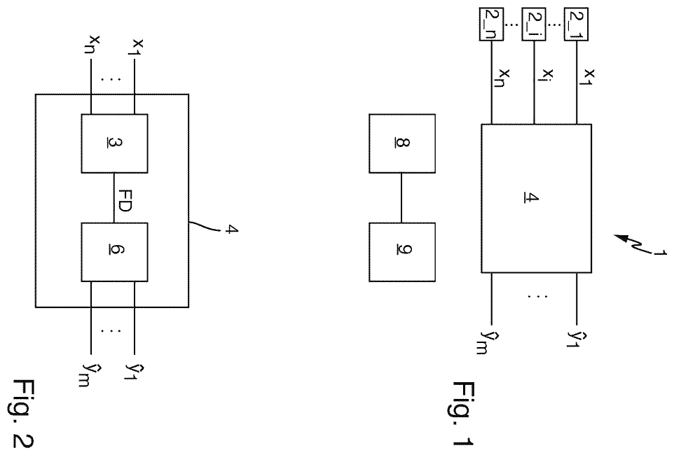

FIG. 1 shows highly schematically a block diagram of a measurement device 1 for process metrology.

The measurement device 1 for process metrology comprises a number n of sensors 2_1 to 2_n, wherein a respective sensor 2_i of the number n of sensors 2_1 to 2_n is designed to generate associated sensor data xᵢ, so that a total number n of sensor data x₁, . . . , xₙ is generated by means of the number n of sensors 2_1 to 2_n.

The measurement device 1 for process metrology further comprises a measurement device diagnostic unit 4, which is designed to calculate a number m of diagnostic values y₁, . . . , yₘ in dependence on the number n of sensor data x₁, . . . , xₙ based on values of a number d of parameters θ₁, . . . , θ_{d}.

Referring to FIG. 4, the measurement device 1 for process metrology comprises a learning unit 5, wherein the learning unit 5 is designed to calculate the values of the number d of parameters θ₁, . . . , θ_{d} based on training data xt₁⁽ⁱ⁾, . . . , xtₙ⁽ⁱ⁾; ys₁⁽ⁱ⁾, . . . , ysₘ⁽ⁱ⁾.

In addition to further components, the measurement device 1 for process metrology comprises a conventional photomultiplier 8 and a voltage supply 9 for the photomultiplier 8.

The measurement device 1 for process metrology converts input variables in the form of sensor values x₁, . . . , xₙ, which can also be time-shifted, into output variables in the form of diagnostic values y₁, . . . , yₘ.

The conversion depends on the model parameters θ₁, . . . , θ_{d}, which are initially unknown and are learned by means of the learning unit 5 using what is known as machine learning. Recorded training data, also called learning data, are used here, which can be formed from real recorded data during operation and/or from simulation data.

Machine learning means that the measurement device for process metrology artificially generates knowledge from experience. The measurement device for process metrology learns from examples and can generalize them after the learning phase has been completed. This means that the examples are not simply memorized, but the measurement device for process metrology recognizes patterns and laws in the training data. It can also assess unknown data (learning transfer).

The measurement device for process metrology preferably uses learning techniques from what is known as supervised learning, in which the measurement device for process metrology learns a diagnostic function from given pairs of inputs and outputs. During learning, the correct diagnostic values for a number n of sensor data are provided, for example based on a reference measurement or simulation.

The measurement device thus formally approximates a diagnostic function

$$f : ( {x}_{1} , … , {x}_{n} ) ↦ ( {y}_{1} , … , {y}_{m} ) ,$$

which maps n input variables or sensor data (x₁, . . . , xₙ) to m output variables or diagnostic values (y₁, . . . , yₘ), by means of a suitable hypothesis function

$${h}_{θ} : ( {x}_{1} , … , {x}_{n} ) ↦ ( {\hat{y}}_{1} , … , {\hat{y}}_{m} ) ,$$

which maps the n sensor data (x₁, . . . , xₙ) to m estimated values (ŷ₁, . . . , ŷₘ) for the (y₁, . . . , yₘ) and depends on the model parameters θ:=(θ₁, . . . , θ_{d}).

Each of the d individual model parameters θᵢ is understood to be one of the following three things:
a mathematical object, in particular
   a number
   a vector
   a function;
a parameterized piece of program logic or source code;
a piece of program logic or source code generated by a code generator.

The model parameters (θ₁, . . . , θ_{d}) are learned from training data by the learning algorithm. More precisely, training data consist of l (wherein l lies for example in a range between 10⁵ and 10⁷, in particular l=10⁶) training pairs (xt⁽¹⁾, ys⁽¹⁾), . . . , (xt^{(l)}, ys^{(l)}), each of which, for example, have the dimension n+m and, for example, each of which consists of a complete set of input data or training sensor data xt⁽ⁱ⁾:=(xt₁⁽ⁱ⁾, . . . , xtₙ⁽ⁱ⁾) plus associated setpoints ys⁽ⁱ⁾:=(ys₁⁽ⁱ⁾, . . . , ysₘ⁽ⁱ⁾) of the number m of diagnostic values, wherein i=1, . . . , l. The setpoints (ys₁⁽ⁱ⁾, . . . , ysₘ⁽ⁱ⁾) are also referred to as training labels.

Based on the training sensor data (xt₁⁽ⁱ⁾, . . . , xtₙ⁽ⁱ⁾), the measurement device diagnostic unit 4 calculates the training values (yt₁⁽ⁱ⁾, . . . , ytₘ⁽ⁱ⁾:=h_{θ}(xt₁⁽ⁱ⁾, . . . , xtₙ⁽ⁱ⁾) of the number m of diagnostic values (y₁, . . . , yₘ) dependent on the parameters (θ₁, . . . , θ_{d}). The learning unit 5 is designed to calculate the values of the parameters (θ₁, . . . , θ_{d}) for i=1, . . . , l based on the setpoints (ys₁⁽ⁱ⁾, . . . , ysₘ⁽ⁱ⁾) and the training values (yt₁⁽ⁱ⁾, . . . , ytₘ⁽ⁱ⁾).

The calculation of the model parameters (θ₁, . . . , θ_{d}) can be performed iteratively several times. This means that random start parameters (θ₁, . . . , θ_{d}) are used at the start. These are then iteratively improved by repeatedly calculating all (yt₁⁽ⁱ⁾, . . . , ytₘ⁽ⁱ⁾) based on the respective current (θ₁, . . . , θ_{d}) and then calculating therefrom new, improved (θ₁, . . . , θ_{d}) until a predefinable quality measure is reached (for example, a minimum of a cost function). Also, in each iteration step, only a subset of the total l datasets (yt₁⁽ⁱ⁾, . . . , ytₘ⁽ⁱ⁾), known as a mini-batch, can be used to calculate new (θ₁, . . . , θ_{d}). This means that several iterations may be required to take into account the entire training data, known as a training epoch.

For example, the learning algorithm is performed once when the measurement device for process metrology is commissioned or repeatedly in real time during the operation of the measurement device for process metrology, e.g. by additional reference measurements.

FIG. 2 shows highly schematically a block diagram of an inner structure of an embodiment of a measurement device diagnostic unit 4 of the measurement device 1 for process metrology shown in FIG. 1.

The measurement device diagnostic unit 4 comprises an optional feature extraction unit 3, which is designed to extract feature data FD from the number n of sensor data x₁, . . . , xₙ, in particular based on the values of the number d of parameters θ₁, . . . , θ_{d}.

The measurement device diagnostic unit 4 further comprises an artificial intelligence (AI) unit 6, which is designed to calculate the number m of diagnostic values y₁, . . . , yₘ from the feature data FD based on the values of the number d of parameters θ₁, . . . , θ_{d}.

Suitable features FD are first extracted from the “raw” sensor data or measurement data x₁, . . . , xₙ and transformed in order to generate as meaningful input data for the AI unit 6 as possible. In particular, one or more of the following techniques are used herefor: principal component analysis (PCA), discriminant analysis, statistical normalization, polynomial transformation, exponential transformation, logarithmic transformation.

It is understood that the feature extraction can also be dispensed with, so that the AI unit 6 uses the unpreprocessed raw sensor data x₁, . . . , xₙ.

Depending on the measurement application, the AI unit 6 calculates a continuous output signal (regression method) or a discrete output signal (classification method). It is realized by an AI model from one of the following four categories:
1.) Models that compare the input values with the stored training data in one or more stages via metrics or suitable similarity functions and then assign them the output values of those training data that are in a certain way “near” or similar.
   For example, this can be one of the following two AI models:
      k nearest-neighbor classification
      k nearest-neighbor regression
   Metrics or similarity features used may include:
      p-norm
      Minkowski distance
      Kullback-Leibler divergence
2.) Models that calculate threshold values from the training data with which the given input values are then compared in multiple stages, usually recursively, in order to determine the associated output values.
   For example, this can be one of the following two AI models:
      decision tree classification
      decision tree regression
3.) Models that estimate transition probabilities from the training data and combine them (possibly in multiple stages) through addition and multiplication using the Bayes-theorem in order to estimate for given input values a univariate or multivariate probability distribution on the output values. The output values with the highest probabilities are then assigned to the input values.
   For example, this can be one of the following two AI models:
      Bayes classifier, in particular Naive Bayes classifier
      Bayesian Network classifier
4.) Models that use linear algebra methods to apply what is known as activation functions to linear combinations and/or convolutions of the transformed or untransformed input values in a single stage or in multiple stages in order to calculate therefrom the output values.
   For example, this can be one of the following two AI models:
      multiclass support vector machine (SVM) with One-Vs-One or One-Vs-All.
         The kernel functions used can include in particular:
         polynomial kernel
         Gaussian RBF kernel
         Laplace RBF kernel
         sigmoid kernel
         hyperbolic tangent kernel
         Anova kernel
         linear splines kernel
      artificial neural network (ANN) and/or deep neural network (DNN)
      Activation functions used can include in particular:
         identity
         sigmoid
         hyperbolic tangent
         ReLu
         Softmax
         Signum

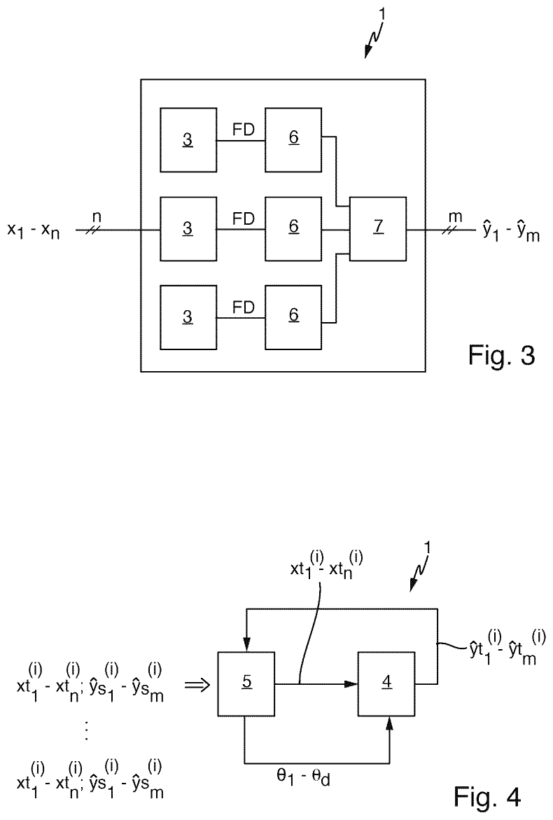

Referring to FIG. 3, which shows highly schematically a block diagram of an inner structure of a further embodiment of a measurement device diagnostic unit 4 of the measurement device 1 for process metrology shown in FIG. 1, optionally, a number of a plurality of individual AI units 6 of the above categories can be combined into a more powerful overall model using ensemble learning. In FIG. 3, three feature extraction units 3 and three AI units 6, each connected downstream thereof, work in parallel, wherein what is known as an ensemble combiner 7 combines the respective data. For example, what is known as bagging or boosting can be used as an ensemble learning technique.

The model parameters (θ₁, . . . , θ_{d}) of the AI unit(s) 6 are determined from the training data by means of machine learning, for example by one of the following techniques:
by once or repeatedly minimizing metrics or maximizing similarity functions. In particular, these can be one or more of the following:
   entropy
   Gini Impurity
   variance
   p-norm
   Minkowski distance
   Kullback-Leibler divergence
by once or repeatedly minimizing a cost function, which depends on the chosen AI model and whose function arguments consist of the training data and the model parameters. The minimization can be subject to certain mathematical constraints (restriction of the search area), which may also depend on the training data and/or model parameters. The cost function is minimized in terms of model parameters, using mathematical optimization methods and techniques, in particular one or more of the following:
   backpropagation
   gradient descent based method
   stochastic gradient descent based method (for example AdaGrad, RMSProp or Adam)
   Gauss-Newton method
   quasi-Newton method
   linear programming
   quadratic programming

Minimizing a cost function may include maximizing a quality function, in particular a maximum likelihood function or a maximum A-posteriori probability function, in particular by changing the mathematical sign.

In order to prevent overfitting, to improve the ability to transfer learning and thus to increase the performance of the AI unit(s) 6, additional regularization techniques can be used in the learning process, such as:
p-norm penalty terms (L1, L2, etc.)
dropout
batch normalization.

Unless otherwise defined, all AI terms should be understood in accordance with the standard academic literature for AI and machine learning. See in particular:
1. Bishop, Christopher M.: “Pattern Recognition and Machine Learning”
2. Mitchell, Tom M.: “Machine Learning”
3. Russell, Stuart J. and Norvig, Peter: “Artificial Intelligence: A Modern Approach”
4. Richard O. Duda and Hart, Peter E. and David G. Stork: “Pattern Classification”
5. Aggarwal, Charu C.: “Neural Networks and Deep Learning: A Textbook”

The foregoing disclosure has been set forth merely to illustrate the invention and is not intended to be limiting. Since modifications of the disclosed embodiments incorporating the spirit and substance of the invention may occur to persons skilled in the art, the invention should be construed to include everything within the scope of the appended claims and equivalents thereof.

What is claimed is:

1. A measurement device for process metrology, comprising:
a number n of sensors (2_1 to 2_n), wherein a respective sensor (2_i) of the number n of sensors (2_1 to 2_n) is designed to generate associated sensor data (xᵢ) such that a total number n of sensor data (x₁, . . . , xₙ) is generated via the number n of sensors (2_1 to 2_n);
a learning unit, wherein the learning unit is configured to calculate values of a number d of parameters (θ₁, . . . , θ_{d}) of a hypothesis function (h_{θ}) based on training data ((xt₁⁽ⁱ⁾, . . . , xtₙ⁽ⁱ⁾); (ŷs₁⁽ⁱ⁾, . . . , ŷsₘ⁽ⁱ⁾); and
a measurement device diagnostic unit, which is configured to calculate a number m of diagnostic values (ŷ₁, . . . , ŷₘ) in dependence on the number n of sensor data (x₁, . . . , xₙ) based on the hypothesis function (h_{θ}) and the calculated values of the number d of parameters (θ₁, . . . , θ_{d}) of the hypothesis function (h_{θ}).

2. The measurement device according to claim 1, wherein
the number m of diagnostic values (ŷ₁, . . . , ŷₘ) relate to a remaining useful life and/or a status of components of the measurement device.

3. The measurement device according to claim 2, further comprising:
a photomultiplier; and
a power supply for the photomultiplier,
wherein the number m of diagnostic values (ŷ₁, . . . , ŷₘ) relate to the remaining useful life and/or the status of the photomultiplier and the power supply.

4. The measurement device according to claim 3, wherein
the number n of sensors is selected from a set of sensors comprising:
at least one sensor configured to detect a signal form of an analog pulse generated by the photomultiplier,
at least one sensor configured to detect a temporal distribution between two analog pulses generated by the photomultiplier,
at least one sensor configured to detect a radiometric spectrum, and
at least one sensor configured to detect a change over time of a radiometric spectrum.
